(19) United States
(12) Patent Application Publication
(10) Pub. No.: US 2025/0340757 A1
(43) Pub. Date: Nov. 6, 2025

(54) ADHESIVE SHEET, ADHESIVE SHEET EQUIPPED WITH MOLD RELEASE FILM, LAMINATE FOR IMAGE DISPLAY DEVICES, AND FLEXIBLE IMAGE DISPLAY DEVICE

(71) Applicant: MITSUBISHI CHEMICAL CORPORATION, Tokyo (JP)

(72) Inventors: Kohei HIROSE, Tokyo (JP); Akifumi MATSUSHITA, Tokyo (JP); Kazunari MATSUMURA, Tokyo (JP)

(73) Assignee: MITSUBISHI CHEMICAL CORPORATION, Tokyo (JP)

(21) Appl. No.: 19/271,726

(22) Filed: Jul. 16, 2025

Related U.S. Application Data
(63) Continuation of application No. PCT/JP2024/000537, filed on Jan. 12, 2024.

(30) Foreign Application Priority Data
Jan. 23, 2023 (JP) 2023-008193

(51) Int. Cl. C09J 7/38; C09J 133/08

(52) U.S. Cl. CPC C09J 7/385; C09J 133/08; C09J 2203/318; C09J 2301/302; C09J 2301/414; C09J 2433/00

(57) ABSTRACT

The present disclosure relates to an adhesive satisfying the following requirement (1) and requirement (2): Requirement (1): a refractive index of the adhesive sheet is 1.480 or more and less than 1.550, Requirement (2): a storage shear modulus (G′(−20° C.)) at −20° C., which is obtained by a dynamic viscoelasticity measurement in a shear mode at a frequency of 1 Hz, is 10 kPa or more and 1,000 kPa or less.

### BACKGROUND

The present disclosure relates to an adhesive sheet, an adhesive sheet equipped with a mold release film, a laminate for image display devices, and a flexible image display device.

This application is a continuation application of International Application No. PCT/JP2024/537, filed on Jan. 12, 2024, which claims the benefit of priority of the prior Japanese Patent Application No. 2023-8193 filed in Japan on Jan. 23, 2023, the content of which is incorporated herein by reference.

### DESCRIPTION OF RELATED ART

An image display device has a laminated structure in which a plurality of members such as a surface protective film, a cover lens, a circularly polarizing plate, a touch film sensor, and a light emitting element are bonded to each other with a transparent adhesive sheet. Each laminated structure in the image display device can be regarded as a laminated sheet in which the member and the adhesive sheet are laminated.

In recent years, a flexible image display device using an organic light emitting diode (OLED) or a quantum dot (QD) has been developed and widely commercialized. Examples of the flexible image display device include a bendable type with an image display surface having a curved shape, a foldable type which can be repeatedly folded, a rollable type which can be rolled up, and a stretchable type which can be stretched and contracted.

The laminated sheet of the flexible image display device needs not only optical characteristics but also flexibility, particularly high durability against folding.

The bendable flexible display device has various problems due to interlayer stress when being bent. For example, a laminated sheet of the bendable display device is required to be quickly restored to a flat state without leaving an influence of being placed in a bent state in a case where the screen is opened from a folded state. In addition, while the folding operation is repeated, the adhesive sheet may be peeled off, or the member as an adherend may be stressed so as to cause a crack in the member, and finally, the member may be broken. In particular, it is also required that the laminated sheet has durability in the folding operation under repeated conditions at a low temperature, which is a severe condition.

Japanese Unexamined Patent Application, First Publication No. 2020-196255 discloses a laminated film with an adhesive layer, in which an image displayed at a folded part after repeated folding is unlikely to be disturbed.

PCT International Publication No. WO 2018/173896 discloses a laminate in which breakage or peeling does not occur even by a bending test close to an actual use environment. The laminate includes a double-sided adhesive sheet having a glass transition temperature and a storage elastic modulus in a predetermined range, and a flexible member for constituting an image display device.

In the laminated sheet of the image display device, due to a difference in refractive index between the adhesive sheet and the member, light scattering or the like occurs at an interface between the adhesive sheet and the member; and as a result, there is a problem in that light transmittance of the laminated sheet is reduced or unevenness occurs in the displayed image. Such a problem is more remarkable when a surface of the member has unevenness or in a bending part of the flexible image display device. Therefore, in order to reduce the difference in refractive index between the adhesive sheet and the member, there is an increasing demand for an adhesive sheet having a high refractive index.

Japanese Unexamined Patent Application, First Publication No. 2020-132875 discloses an adhesive layer containing a base polymer having a glass transition temperature of 5° C. or lower, the adhesive layer having a refractive index of 1.54 or more and being used as an adhesive layer for bonding various optical members.

### SUMMARY

However, in each of the techniques disclosed in Patent Documents 1 and 2, although durability during folding is considered, the refractive index of the adhesive sheet is not considered.

The adhesive layer disclosed in Japanese Unexamined Patent Application, First Publication No. 2020-132875 has a high refractive index, but contains a large amount of a high refractive index monomer for increasing the refractive index and thus has a high glass transition temperature of the adhesive, and is not flexible, so that flexibility is not considered. Further improvement is required in achieving both flexibility and a high refractive index.

An object of the present disclosure is to provide an adhesive sheet which has a high refractive index, is flexible, and is exceptional in flexibility, an adhesive sheet equipped with a mold release film, using the adhesive sheet, a laminate for image display devices, and a flexible image display device.

The present disclosure includes the following aspects.

[1] An adhesive sheet formed from an adhesive composition,
wherein the adhesive composition contains a (meth)acrylic copolymer (A), and
the following requirements (1) and (2) are satisfied,
the requirement (1): a refractive index of the adhesive sheet is 1.480 or more and less than 1.550,
the requirement (2): a storage shear modulus (G′(−20° C.)) at −20° C., which is obtained by a dynamic viscoelasticity measurement in a shear mode at a frequency of 1 Hz, is 10 kPa or more and 1,000 kPa or less.

[2] The adhesive sheet according to [1],
wherein the (meth)acrylic copolymer (A) has a unit derived from an aromatic (meth)acrylate (a 1) having a refractive index of 1.500 or more.

[3] The adhesive sheet according to [2],
wherein a glass transition temperature (Tg) of a homopolymer of the aromatic (meth)acrylate (a 1) is 60° C. or lower.

[4] The adhesive sheet according to [2] or [3],
wherein a proportion of the unit derived from the aromatic (meth)acrylate (a 1) to all units of the (meth)acrylic copolymer (A) is 1% to 50% by mass.

[5] The adhesive sheet according to any one of [1] to [4],
wherein a glass transition temperature (Tg) defined by a maximal value of Tan δ, which is obtained by the dynamic viscoelasticity measurement in the shear mode at the frequency of 1 Hz, is −20° C. or lower.

[6] The adhesive sheet according to any one of [1] to [5],
wherein the adhesive composition further contains a photoinitiator (B).

[7] The adhesive sheet according to any one of [1] to [5],
wherein the adhesive composition further contains a photocurable compound (C).

[8] The adhesive sheet according to any one of [1] to [5],
wherein the adhesive composition further contains a photoinitiator (B) and a photocurable compound (C).

[9] The adhesive sheet according to any one of [1] to [8],
wherein a ratio (G′(−20° C.)/G′(60° C.)) of the storage shear modulus G′(−20° C.) at −20° C. to a storage shear modulus G′(60° C.) at 60° C., which is obtained by the dynamic viscoelasticity measurement in the shear mode at the frequency of 1 Hz, is 150 or less.

[10] The adhesive sheet according to any one of [1] to [9],
wherein a restoration rate calculated by the following expression from a maximum strain value (γₘₐₓ) when a stress of 2 kPa is applied to the adhesive sheet at 60° C. for 600 seconds and a residual strain value (γₘᵢₙ) after 600 seconds from a point in time that the stress is removed is 60% or more,

$$the restoration rate ( \% ) = [ ( {γ}_{max} - {γ}_{min} ) / {γ}_{max} ] \times 100.$$

[11] The adhesive sheet according to any one of [1] to [10],
wherein a gel fraction is 30% or more.

[12] The adhesive sheet according to any one of [1] to [11],
wherein the (meth)acrylic copolymer (A) has a unit derived from an alkyl (meth)acrylate with an alkyl group having 9 to 30 carbon atoms.

[13] The adhesive sheet according to any one of [1] to [12],
wherein the (meth)acrylic copolymer (A) is a block copolymer or a graft copolymer.

[14] The adhesive sheet according to any one of [1] to [13],
wherein the (meth)acrylic copolymer (A) has a unit derived from a macromonomer (a 10).

[15] The adhesive sheet according to [14],
wherein the macromonomer (a 10) has a unit derived from an alkyl (meth)acrylate with an alkyl group having 9 to 30 carbon atoms.

[16] The adhesive sheet according to [14] or [15],
wherein the (meth)acrylic copolymer (A) further has a unit derived from an aromatic (meth)acrylate (a 1) having a refractive index of 1.500 or more, and
a proportion (a 10/a 1) of the unit derived from the macromonomer (a 10) to the unit derived from the aromatic (meth)acrylate (a 1) in the (meth)acrylic copolymer (A) is 0.1 to 10 in terms of weight ratio.

[17] The adhesive sheet according to any one of [1] to [16],
wherein the adhesive sheet is used for bonding a member having unevenness on a surface and a member having an organic light emitting diode.

[18] An adhesive sheet equipped with a mold release film, comprising:
the adhesive sheet according to any one of [1] to [17]; and
a mold release film laminated on at least one surface of the adhesive sheet.

[19] The adhesive sheet according to any one of [1] to [17],
wherein the adhesive sheet is used for a flexible image display device constituent member.

[20]A laminate for image display devices, comprising:
two image display device constituent members; and
the adhesive sheet according to any one of [1] to [17],
wherein the two image display device constituent members are laminated through the adhesive sheet, and
at least one of the two image display device constituent members has a step with a height difference of 2 μm or more on a contact surface with the adhesive sheet.

[21]A flexible image display device comprising:
the laminate for image display devices according to [20].

According to the present disclosure, it is possible to provide an adhesive sheet which has a high refractive index, is flexible, and is exceptional in flexibility, an adhesive sheet equipped with a mold release film, using the adhesive sheet, a laminate for image display devices, and a flexible image display device.

### DETAILED DESCRIPTION

Meanings of terms are as follows.

“(Meth)acrylate” is a generic term for acrylate and methacrylate. The same applies to “(meth)acryloyl group”, “(meth)acrylic acid”, “(meth)acrylonitrile”, and “(meth)acrylamide”.

“(Meth)acrylic copolymer” means a copolymer having a unit derived from a (meth)acrylic monomer. The (meth)acrylic copolymer may further have units derived from monomers other than (meth)acrylic monomers (for example, styrene and the like).

“(Meth)acrylic monomer” means a monomer having a (meth)acryloyl group.

“Vinyl monomer” means a compound having an ethylenically unsaturated bond (polymerizable carbon-carbon double bond).

The expression “to” indicating a numerical value range means that numerical values described before and after the expression are included as a lower limit value and an upper limit value, and also includes the meaning of “preferably equal to or more than the lower limit value” or “preferably equal to or less than the upper limit value”.

In addition, when described as “x or more” (x is any number), unless otherwise specified, the description includes the meaning of “preferably more than x”; and when described as “y or less” (y is any number), unless otherwise specified, the description includes the meaning of “preferably less than y”.

Furthermore, “x and/or y (x and y are optional configurations)” means at least one of x or y, and means three cases of only x, only y, and x and y.

### [Adhesive Sheet]

An embodiment of the present disclosure relates to an adhesive sheet.

The adhesive sheet according to the embodiment is formed from an adhesive composition containing a (meth)acrylic copolymer (A).

It is preferable that the adhesive composition further contains a photoinitiator (B).

It is preferable that the adhesive composition further contains a photocurable compound (C).

The adhesive composition may further contain a component other than the (meth)acrylic copolymer (A), the photoinitiator (B), and the photocurable compound (C).

When the adhesive composition has active energy ray curability, the adhesive sheet according to the embodiment is typically obtained by curing the adhesive composition containing the (meth)acrylic copolymer (A). In an example, the adhesive sheet is in a state after the active energy ray curable adhesive composition is cured.

The adhesive sheet according to the embodiment satisfies the following requirement (1).
(1) A refractive index of the adhesive sheet is 1.480 or more and less than 1.550.

The adhesive sheet satisfying the requirement (1) can reduce a difference in refractive index between the image display device constituent member and the adhesive sheet, and can suppress diffuse reflection or optical unevenness caused by the difference in refractive index.

From the viewpoint of further reducing the difference in refractive index, the refractive index in the requirement (1) is preferably 1.482 or more, more preferably 1.485 or more, and still more preferably 1.490 or more. From the same viewpoint, the refractive index in the requirement (1) is preferably 1.570 or less, more preferably 1.560 or less, still more preferably 1.550 or less, and particularly preferably 1.520 or less. The lower limit and upper limit of the refractive index in the requirement (1) can be arbitrarily combined.

The refractive index in the requirement (1) is a value on a surface of the adhesive sheet.

The refractive index in the requirement (1) is measured using an Abbe refractometer under conditions of a wavelength of 589 nm and 23° C.

Examples of a method of adjusting the refractive index in the requirement (1) include a method of adjusting a formulation or molecular weight of the (meth)acrylic copolymer, a kind or amount of the photocurable compound, a method of blending a refractive index adjusting agent, and the like. For example, when the (meth)acrylic copolymer (A) contains a unit derived from an aromatic (meth)acrylate (a 1) having a refractive index of 1.500 or more, the refractive index in the requirement (1) can be set to 1.480 or more. However, the method is not limited to these methods.

Examples of the refractive index adjusting agent include high refractive index nanoparticles such as zirconium oxide particles, niobium oxide particles, tin oxide particles (including phosphorus-doped tin oxide particles and fluorine-doped tin oxide particles), diamond particles, and titanium oxide particles; and a monomer, a resin, or a polymer having a substituted or unsubstituted aromatic group. As the refractive index adjusting agent, one or more kinds can be appropriately selected not only depending on the refractive index but also depending on other characteristics required for the adhesive sheet.

The adhesive sheet according to the embodiment further satisfies the following requirement (2).
(2) A storage shear modulus (G′(−20° C.)) at −20° C., which is obtained by a dynamic viscoelasticity measurement in a shear mode at a frequency of 1 Hz, is 10 kPa or more and 1,000 kPa or less.

The adhesive sheet satisfying the requirement (2) is flexible even at a low temperature and has exceptional flexibility. For example, even when a folding operation is repeatedly performed at a low temperature of −20° C., cracks or breakage are less likely to occur in a member which is an adherend of the adhesive sheet.

From the viewpoint of shape holding power of the adhesive sheet when not bonded, the G′(−20° C.) in the requirement (2) is preferably 30 kPa or more, more preferably 50 kPa or more, and still more preferably 100 kPa or more. On the other hand, from the viewpoint of flexibility of the adhesive sheet in a low-temperature environment, the G′(−20° C.) in the requirement (2) is preferably 800 kPa or less, more preferably 600 kPa or less, still more preferably 400 kPa or less, and particularly preferably 300 kPa or less. The lower limit and upper limit of G′(−20° C.) in the requirement (2) can be arbitrarily combined.

In order to accurately measure the storage shear modulus G′, it is necessary to avoid fluctuations in measurement results due to influence of a measurement jig by insufficient thickness of the adhesive sheet. The requirement (2) is a value measured after adjusting the thickness to a range of 0.7 to 1.0 mm, and thus the storage shear modulus G′ can be accurately measured without being affected by the measurement jig.

The “adjusting the thickness to a range of 0.7 to 1.0 mm” means that, when the thickness of the adhesive sheet used as a measurement sample is not within this range, the thickness of the measurement sample is adjusted to within this range by stacking several sheets. The same applies to other tests when the thickness of the measurement sample is defined.

For example, the measurement of the G′(−20° C.) in the requirement (2) is carried out as follows.

After repeatedly laminating the adhesive sheet to adjust the thickness thereof to 0.7 to 1.0 mm, a circular sample having a diameter of 8 mm is punched out. A dynamic viscoelasticity measurement of the obtained sample is performed using a rheometer under the conditions of a measurement jig of 8 mm-diameter parallel plate, a frequency of 1 Hz, a measurement temperature of −50° C. to 150° C., and a temperature rising rate of 5° C./min, and a value of a storage shear modulus (G′) at −20° C. is read.

Examples of a method of adjusting G′(−20° C.) of the requirement (2) in the adhesive sheet to the above-described range include a method of adjusting the formulation or molecular weight of the (meth)acrylic copolymer (A) and the kind or addition amount of the photocurable compound (C). However, the method is not limited to these methods.

It is preferable that the adhesive sheet according to the embodiment further satisfies the following requirement (3).

(3) A glass transition temperature (Tg) defined by a maximal value of Tan δ, which is obtained by a dynamic viscoelasticity measurement in a shear mode at a frequency of 1 Hz, is −20° C. or lower.

The adhesive sheet satisfying the requirement (3) has exceptional flexibility.

From the viewpoint of obtaining exceptional flexibility, Tg in the requirement (3) is preferably −25° C. or lower, more preferably −28° C. or lower, still more preferably −30° C. or lower, and particularly preferably −35° C. or lower. On the other hand, the lower limit thereof is usually −80° C.

Examples of a method of adjusting Tg in the requirement (3) to the above-described range include a method of adjusting the formulation or molecular weight of the (meth)acrylic copolymer (A) and the kind or addition amount of the photocurable compound (C), and a method of controlling the amount of irradiation with active energy rays. However, the method is not limited to these methods.

It is preferable that the adhesive sheet according to the embodiment further satisfies the following requirement (4).

(4) A ratio (G′(−20° C.)/G′(60° C.)) of the storage shear modulus G′(−20° C.) at −20° C. to a storage shear modulus G′(60° C.) at 60° C., which is obtained by a dynamic viscoelasticity measurement in a shear mode at a frequency of 1 Hz, is 150 or less.

The adhesive sheet satisfying the requirement (4) has an exceptional balance between flexibility in a low-temperature environment and an adhesive force.

From the viewpoint of improving the flexibility in a low-temperature environment, G′(−20° C.)/G′(60° C.) in the requirement (4) is preferably 100 or less, more preferably 80 or less, still more preferably 50 or less, particularly preferably 40 or less, and most preferably 30 or less. On the other hand, from the viewpoint of improving the high adhesive force, G′(−20° C.)/G′(60° C.) in the requirement (4) is preferably 3 or more, more preferably 5 or more, and still more preferably 10 or more. The above-described lower limit and upper limit of G′(−20° C.)/G′(60° C.) in the requirement (4) can be arbitrarily combined.

The measurement of G′(−20° C.) in the requirement (4) is the same as the measurement of G′(−20° C.) in the requirement (2). The measurement of G′(60° C.) in the requirement (4) is the same as the measurement of G′(−20° C.) in the requirement (2), except that the value of the storage shear modulus (G′) at 60° C. is read.

Examples of a method of adjusting G′(−20° C.)/G′(60° C.) in the requirement (4) to the above-described range include a method of adjusting the formulation or molecular weight of the (meth)acrylic copolymer (A) and the kind or addition amount of the photocurable compound, and a method of controlling the amount of irradiation with active energy rays. However, the method is not limited to these methods.

It is preferable that the adhesive sheet according to the embodiment further satisfies the following requirement (5).

(5) A restoration rate calculated by the following expression from a maximum strain value (γₘₐₓ) when a stress of 2 kPa is applied to the adhesive sheet at 60° C. for 600 seconds and a residual strain value (γₘᵢₙ) after 600 seconds from the point in time that the stress is removed is 60% or more.

$$Restoration rate ( \% ) = [ ( {γ}_{max} - {γ}_{min} ) / {γ}_{max} ] \times 100$$

The adhesive sheet satisfying the requirement (5) has exceptional restoring properties during folding.

From the viewpoint of obtaining an adhesive sheet having exceptional restoring properties during folding, the restoration rate in the requirement (5) is preferably 65% or more, more preferably 70% or more, still more preferably 75% or more, particularly preferably 80% or more, and most preferably 85% or more. On the other hand, from the viewpoint of improving the adhesive force, the restoration rate in the requirement (5) is preferably 99% or less, more preferably 98% or less, and still more preferably 97% or less. The lower limit and upper limit of the restoration rate in the requirement (5) can be arbitrarily combined.

For example, the measurement of the restoration rate in the requirement (5) is carried out as follows.

After repeatedly laminating the adhesive sheet to adjust the thickness thereof to 0.7 to 1.0 mm, a circular sample having a diameter of 8 mm is punched out. For the obtained sample, a strain (yₘₐₓ) after applying a pressure of 2 kPa at 60° C. for 600 seconds and a strain (7 min) after the stress is released and 600 seconds have elapsed are measured using a rheometer. The obtained values are substituted into the following expression to calculate the restoration rate.

$$Restoration rate ( \% ) = [ ( {γ}_{max} - {γ}_{min} ) / {γ}_{max} ] \times 100$$

Examples of a method of adjusting the restoration rate in the requirement (5) to the above-described range include a method of adjusting the formulation or molecular weight of the (meth)acrylic copolymer (A) and the kind or addition amount of the photocurable compound, and a method of controlling the amount of irradiation with active energy rays. However, the method is not limited to these methods.

It is preferable that the adhesive sheet according to the embodiment further satisfies the following requirement (6).

(6) A gel fraction of the adhesive sheet is 30% or more.

The adhesive sheet satisfying the requirement (6) has exceptional cohesive force.

From the viewpoint of improving the cohesive force, the gel fraction in the requirement (6) is preferably 35% or more, more preferably 40% or more, and still more preferably 45% or more. On the other hand, from the viewpoint of obtaining the adhesive force, the gel fraction in the requirement (6) is preferably 90% or less, more preferably 87% or less, and still more preferably 85% or less. The lower limit and upper limit of the gel fraction in the requirement (6) can be arbitrarily combined.

For example, the measurement of the gel fraction in the requirement (6) is carried out as follows.

A pre-weighed adhesive sheet is wrapped in an SUS wire mesh of 150 mesh, and immersed in ethyl acetate at 23° C. for 24 hours. Thereafter, the adhesive sheet is dried at 70° C. for 4.5 hours, the mass of the adhesive before and after the immersion in ethyl acetate is measured, and the difference between the masses is defined as the mass (mass after immersion) of the adhesive remaining in the wire mesh in an insoluble state. The percentage of the mass of the insoluble adhesive agent remaining in the wire mesh (mass after immersion) with respect to the mass of the adhesive before immersion in ethyl acetate (mass before immersion) is calculated as the gel fraction (%) in the requirement (6).

Examples of a method of adjusting the gel fraction in the requirement (6) to the above-described range include a method of adjusting the formulation or molecular weight of the (meth)acrylic copolymer (A) and the kind or addition amount of the photocurable compound, and a method of controlling the amount of irradiation with active energy rays. However, the method is not limited to these methods.

It is preferable that the adhesive sheet according to the embodiment further satisfies the following requirement (7).

(7) When the adhesive sheet is bonded to a polyester film, an adhesive force to a surface of the polyester film at 23° C., 50% RH, a peeling angle of 180°, and a peeling rate of 300 mm/min is 0.5 N/cm or more.

Since the adhesive sheet satisfying the requirement (7) has exceptional pressure-sensitive adhesiveness and delamination is less likely to occur even when a laminate bonded to an adherend such as an image display device constituent member is folded, durability is exceptional.

From the viewpoint of pressure-sensitive adhesiveness of the adhesive sheet, the adhesive force in the requirement (7) is preferably 1 N/cm or more, more preferably 2 N/cm or more, and still more preferably 3 N/cm or more. The upper limit of the adhesive force in the requirement (7) is not particularly limited, and can be, for example, 20 N/cm or less.

For example, the measurement of the adhesive force in the requirement (7) is carried out as follows.

A polyester film is back-coated as a backing film on one surface of the adhesive sheet, and cut into a strip shape having a width of 10 mm and a length of 150 mm to obtain a test piece. The test piece is adhered to a polyester film which has been bonded to soda-lime glass in advance and subjected to an autoclave treatment (60° C., gauge pressure of 0.2 MPa, and 20 minutes) to obtain a measurement sample of adhesive force. For the obtained measurement sample of adhesive force, under the conditions of 23° C., 50% RH, a peeling angle of 180°, and a peeling rate of 300 mm/min, the adhesive sheet is peeled off together with the backing film from the polyester film bonded to the soda-lime glass, and a tensile strength (N/cm) is measured with a load cell to obtain the adhesive force.

Examples of a method of adjusting the adhesive force in the requirement (7) include a method of adjusting the formulation or molecular weight of the (meth)acrylic copolymer (A) and the kind or addition amount of the photocurable compound, and a method of controlling the amount of irradiation with active energy rays. However, the method is not limited to these methods.

It is preferable that the adhesive sheet according to the embodiment further satisfies the following requirement (8).

(8) A total light transmittance is 80% or more.

The adhesive sheet satisfying the requirement (8) has exceptional transparency, and is useful for applications requiring transparency, such as an image display device.

The total light transmittance in the requirement (8) is preferably 85% or more, and more preferably 90% or more. It is preferable that the total light transmittance in the requirement (8) is higher, and the upper limit thereof is not particularly limited.

The measurement of the total light transmittance in the requirement (8) is carried out in conformity with the standard of JIS-K 7361-1 (ISO-13468-1).

It is preferable that the adhesive sheet according to the embodiment further satisfies the following requirement (9).

(9) A haze is 5% or less.

The adhesive sheet satisfying the requirement (9) has exceptional transparency, and is useful for applications requiring transparency, such as an image display device.

The haze in the requirement (9) is preferably 4% or less, more preferably 2% or less, and still more preferably 1% or less. It is preferable that the haze in the requirement (9) is lower, and the lower limit thereof is not particularly limited.

The measurement of the haze in the requirement (9) is carried out in conformity with the standard of JIS-K 7136 (ISO-14782).

As a method of adjusting the total light transmittance in the requirement (8) and the haze of the requirement (9), for example, the formulation of the (meth)acrylic acid ester copolymer may be adjusted, a colorless photoinitiator may be used, or a colorant may not be contained. In addition, coloring due to heating or aging deterioration may be suppressed by using an antioxidant. However, the method is not limited to these methods.

The adhesive sheet according to the embodiment may have a single-layer configuration or a multilayer configuration. When a multilayer configuration, each of the plurality of layers is formed of an adhesive composition containing the (meth)acrylic copolymer (A).

From the viewpoint that handleability is favorable and exceptional unevenness followability is easily obtained, the thickness of the adhesive sheet according to the embodiment is preferably 5 μm or more, more preferably 10 μm or more, still more preferably 15 μm or more, and particularly preferably 20 μm or more. From the viewpoint that it is easy to relieve stress when folding or bending, and it is easy to make a flexible image display device using the adhesive sheet thinner, the thickness of the adhesive sheet according to the embodiment is preferably 100 μm or less, more preferably 80 μm or less, still more preferably 70 μm or less, and particularly preferably 60 μm or less. The lower limit and upper limit of the thickness of the adhesive sheet can be arbitrarily combined.

### ((Meth)Acrylic Copolymer (a))

In the adhesive sheet according to the embodiment, one of the method of adjusting the requirements (1) to (9) is to adjust the formulation of the (meth)acrylic copolymer (A).

Hereinafter, an example of the (meth)acrylic copolymer (A) (hereinafter, also simply referred to as “copolymer (A)”) which can be preferably used in the adhesive sheet according to the embodiment will be described.

From the viewpoint of easily obtaining the adhesive sheet satisfying the requirement (1), the copolymer (A) preferably has a unit derived from an aromatic (meth)acrylate (a 1) having a refractive index of 1.500 or more (hereinafter, also simply referred to as “aromatic (meth)acrylate (a 1)”).

The aromatic (meth)acrylate (a 1) is a (meth)acrylate having one or more aromatic groups in one molecule.

Examples of the aromatic group include phenyl, biphenyl, naphthyl, phenanthrenyl, anthracenyl, and pyrenyl.

The aromatic ring may have one or more substituents. The fact that the aromatic ring has a substituent means that the substituent is bonded to an atom (a carbon atom or the like) constituting a ring skeleton of the aromatic ring. Examples of the substituent include a halogen such as F, Cl, Br, and I, an alkyl having 1 to 10 carbon atoms, an alkoxy having 1 to 10 carbon atoms, and an acyloxy having 2 to 11 carbon atoms.

From the viewpoint of increasing the refractive index, the number of aromatic rings in the aromatic (meth)acrylate (a 1) is preferably 2 or more, and from the viewpoint of compatibility, it is preferably 4 or less.

The aromatic ring may be directly bonded to a (meth)acryloyl group of the aromatic (meth)acrylate (a 1), or may be bonded thereto through a linking group. Examples of the linking group include an alkylene, a (poly)alkylene glycol, an ether, an ester, a urethane, a carbonate, an amide, and a urea.

From the viewpoint of increasing the refractive index of the adhesive sheet, the refractive index of the aromatic (meth)acrylate (a 1) is preferably 1.500 or more, more preferably 1.510 or more, and still more preferably 1.520 or more. In addition, from the viewpoint of ensuring compatibility with other units, the refractive index of the aromatic (meth)acrylate (a 1) is preferably 1.700 or less, more preferably 1.690 or less, still more preferably 1.600 or less, and particularly preferably 1.550 or less. The lower limit and upper limit of the refractive index can be arbitrarily combined.

The refractive index of the aromatic (meth)acrylate (a 1) is determined in accordance with the standard of JIS-K 7142.

As the refractive index of the aromatic (meth)acrylate (a 1), a value described in a catalog or the like may be adopted.

Examples of the aromatic (meth)acrylate (a 1) include m-phenoxybenzyl acrylate (refractive index: 1.566, polymer Tg: −35° C.), o-phenylphenoxyethyl acrylate (refractive index: 1.577, polymer Tg: 33° C.), 2-phenylbenzyl acrylate (refractive index: 1.600, polymer Tg: 6° C.), o-phenylphenol acrylate (refractive index: 1.575, polymer Tg: 82° C.), phenoxyethyl acrylate (refractive index: 1.519, polymer Tg: −22° C.), benzyl acrylate (refractive index: 1.519, polymer Tg: 6° C.), phenoxyethyl methacrylate (refractive index: 1.511, polymer Tg: 54° C.), phenyldiethylene glycol acrylate (refractive index: 1.514, polymer Tg: −8° C.), phenyltetraethylene glycol acrylate (refractive index: 1.507, polymer Tg: −18° C.), nonylphenol ethylene oxide-modified acrylate (refractive index: 1.507, polymer Tg: 17° C.), neopentyl glycol-acrylic acid-benzonic acid ester (refractive index: 1.501), and acrylic acid (1-naphthyl)methyl ester (refractive index: 1.595, polymer Tg: 31° C.); aromatic (meth)acrylates having a polar group such as 2-acryloyloxyethyl phthalic acid (refractive index: 1.517), 2-acryloyloxyethyl-2-hydroxyethyl-phthalic acid (refractive index: 1.523), and 2-hydroxy-3-phenoxypropyl acrylate (refractive index: 1.526); and (meth)acrylates having a benzophenone structure such as 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloxyethoxybenzophenone, 4-methacryloyloxy-4′-methoxybenzophenone, 4-methacryloxyethoxy-4′-methoxybenzophenone, 4-methacryloyloxy-4′-bromobenzophenone, 4-methacryloxyethoxy-4′-bromobenzophenone, and a mixture thereof. The aromatic (meth)acrylate (a 1) can be used alone or in combination of two or more kinds thereof.

Among the above, from the viewpoint of achieving the increase in refractive index while maintaining the flexibility of the adhesive sheet, as the aromatic (meth)acrylate (a 1), m-phenoxybenzyl acrylate, o-phenylphenoxyethyl acrylate, 2-phenylbenzyl acrylate, o-phenylphenol acrylate, phenoxyethyl acrylate, benzyl acrylate, phenyldiethylene glycol acrylate, phenyltetraethylene glycol acrylate, or acrylic acid (1-naphthyl)methyl ester is preferable; m-phenoxybenzyl acrylate, o-phenylphenoxyethyl acrylate, or phenoxyethyl acrylate is more preferable; and m-phenoxybenzyl acrylate is still more preferable.

From the viewpoint of maintaining the flexibility of the adhesive sheet and obtaining bendability, a glass transition temperature of a homopolymer of the aromatic (meth)acrylate (a 1) (hereinafter, also referred to as “polymer Tg”) is preferably 60° C. or lower; and it is more preferably 50° C. or lower, 40° C. or lower, 30° C. or lower, and 20° C. or lower in this order; and it is still more preferably 0° C. or lower, −10° C. or lower, and −20° C. or lower in this order.

On the other hand, the lower limit thereof is usually −70° C. or higher, but from the viewpoint of imparting an appropriate cohesive force to the adhesive sheet, it is preferably −40° C. or higher, more preferably −20° C. or higher, preferably 0° C. or higher, and still more preferably 10° C. or higher.

The lower limit and upper limit of the polymer Tg can be arbitrarily combined.

As the polymer Tg of the aromatic (meth)acrylate (a 1), a value described in a literature, for example, Polymer Handbook [Polymer HandBook, J. Brandrup, Interscience, 1989] or in a catalog of a monomer can be used.

From the viewpoint of increasing the refractive index, a proportion of the unit derived from the aromatic (meth)acrylate (a 1) to all units of the copolymer (A) is preferably 1% by mass or more, more preferably 5% by mass or more, still more preferably 8% by mass or more, particularly preferably 10% by mass or more, and particularly preferably 15% by mass. From the viewpoint of maintaining the flexibility of the adhesive sheet and obtaining bendability, the proportion of the unit derived from the aromatic (meth)acrylate (a 1) to all units of the copolymer (A) is preferably 50% by mass or less, more preferably 40% by mass or less, still more preferably 35% by mass or less, particularly preferably 30% by mass or less, especially preferably 25% by mass or less, and most preferably 20% by mass or less. The lower limit and upper limit of the above-described proportion can be arbitrarily combined.

From the viewpoint of obtaining the flexibility, the copolymer (A) preferably has a unit derived from an alkyl (meth)acrylate (a 2) with an alkyl group having 4 to 30 carbon atoms, in addition to the unit derived from the aromatic (meth)acrylate (a 1).

In addition, from the viewpoint of obtaining exceptional pressure-sensitive adhesiveness, it is preferable that the copolymer (A) has a unit derived from any one or more copolymerizable monomers selected from the group consisting of a carboxy group-containing monomer (a 3), a hydroxyl group-containing monomer (a 4), a nitrogen-containing monomer (a 5), an epoxy group-containing monomer (a 6), a vinyl monomer (a 7), an alkyl (meth)acrylate monomer (a 8) with an alkyl group having 1 to 3 carbon atoms, an alicyclic monomer (a 9), a macromonomer (a 10), and other copolymerizable monomers (all), in addition to the unit derived from the aromatic (meth)acrylate (a 1) and the unit derived from the alkyl (meth)acrylate (a 2) with an alkyl group having 4 to 30 carbon atoms.

Among the copolymerizable monomers (a 3) to (all), any one or more selected from the group consisting of the carboxy group-containing monomer (a 3), the hydroxyl group-containing monomer (a 4), and the nitrogen-containing monomer (a 5) are preferable.

In addition, it is particularly preferable to not include the carboxy group-containing monomer (a 3) and include any one or more selected from the group consisting of the hydroxyl group-containing monomer (a 4) and the nitrogen-containing monomer (a 5). When the copolymer (A) has a unit derived from any one or more selected from the group consisting of the hydroxyl group-containing monomer (a 4) and the nitrogen-containing monomer (a 5), it is possible to achieve anticorrosion properties, adhesiveness, and moisture-heat whitening resistance properties as the adherend contains a component having corrosiveness, such as a metal.

Furthermore, among the nitrogen-containing monomers (a 5), a nitrogen-containing monomer having a tertiary nitrogen atom is preferable from the viewpoint that a sensitizing action of a hydrogen abstraction reaction described later is provided, and as a result, crosslinking can be efficiently formed.

The alkyl (meth)acrylate (a 2) is a linear or branched alkyl (meth)acrylate in which the number of carbon atoms in the alkyl group is 4 to 30 and is represented by Formula (1).

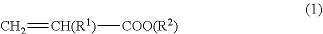

(in the formula, R¹ represents a hydrogen atom or a methyl group, and R² represents a linear or branched alkyl group having 4 to 30 carbon atoms)

Examples of the alkyl (meth)acrylate represented by Formula (1) include linear alkyl (meth)acrylates such as n-butyl (meth)acrylate, n-pentyl (meth)acrylate, n-hexyl (meth)acrylate, n-heptyl (meth)acrylate, n-octyl (meth)acrylate, n-nonyl (meth)acrylate, n-decyl (meth)acrylate, undecyl (meth)acrylate, lauryl (meth)acrylate, n-tridecyl (meth)acrylate, n-tetradecyl (meth)acrylate, cetyl (meth)acrylate, stearyl (meth)acrylate, icosyl (meth)acrylate, henicosyl (meth)acrylate, and behenyl (meth)acrylate; and branched alkyl (meth)acrylates such as sec-butyl (meth)acrylate, isobutyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, isostearyl (meth)acrylate, isoicosyl (meth)acrylate, butyloctyl (meth)acrylate, isomethyl (meth)acrylate, isocetyl (meth)acrylate, hexyldecyl (meth)acrylate, isostearyl (meth)acrylate, octyldecyl (meth)acrylate, octyldodecyl (meth)acrylate, and isobehenyl (meth)acrylate. These may be used alone or in combination of two or more kinds thereof.

Among the above, from the viewpoint of flexibility and pressure-sensitive adhesiveness, the number of carbon atoms in the alkyl group is preferably 4 to 20, more preferably 5 or more, still more preferably 6 or more, particularly preferably 9 or more, and particularly preferably 10 or more; and the number of carbon atoms in the alkyl group is preferably 18 or less, more preferably 16 or less, still more preferably 15 or less, and particularly preferably 14 or less.

In addition, a linear alkyl (meth)acrylate is preferable from the viewpoint of obtaining more flexibility. Moreover, from the viewpoint of balancing the pressure-sensitive adhesiveness and the flexibility, the number of carbon atoms in the alkyl group is preferably 4 to 20, more preferably 5 or more, still more preferably 6 or more, particularly preferably 9 or more, and particularly preferably 10 or more; and the number of carbon atoms in the alkyl group is preferably 18 or less, still more preferably 16 or less, particularly preferably 15 or less, and particularly preferably 14 or less. Examples thereof include n-butyl (meth)acrylate, n-pentyl (meth)acrylate, n-hexyl (meth)acrylate, n-octyl (meth)acrylate, n-nonyl (meth)acrylate, decyl (meth)acrylate, lauryl (meth)acrylate, and tridecyl (meth)acrylate.

In addition, among the above, from the viewpoint that a hydrogen abstraction reaction described later is likely to occur during light irradiation, and as a result, a crosslinking reaction can be efficiently formed, a branched alkyl (meth)acrylate is preferably used, and among these, a branched alkyl (meth)acrylate having, in an alkyl group, 4 to 20 carbon atoms, more preferably 5 to 18 carbon atoms, particularly preferably 6 to 16 carbon atoms, and most preferably 7 to 14 carbon atoms is preferable. For example, sec-butyl (meth)acrylate, isobutyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, or isodecyl (meth)acrylate is preferable.

Among the alkyl (meth)acrylates (a 2), an alkyl (meth)acrylate having a tertiary carbon atom in the alkyl group is preferable. By using such an alkyl (meth)acrylate, the hydrogen abstraction reaction is likely to occur during light irradiation, and as a result, crosslinking is likely to be efficiently formed.

A proportion of the unit derived from the alkyl (meth)acrylate (a 2) to all units of the copolymer (A) is preferably 5% by mass or more and 95% by mass or less, more preferably 10% by mass or more and 90% by mass or less, still more preferably 15% by mass or more and 85% by mass or less, and particularly preferably 20% by mass or more and 80% by mass or less. When the proportion of the unit derived from the alkyl (meth)acrylate is equal to or more than the above-described lower limit value, the flexibility tends to be exceptional, and unevenness followability when the adherend has unevenness tends to be exceptional. When the proportion of the unit derived from the alkyl (meth)acrylate is equal to or less than the above-described upper limit value, an effect of the copolymerizable monomer described later is easily obtained, and the adhesive composition tends to have exceptional adhesive force and cohesive force.

The upper limit and upper limit of the contained amount of the unit derived from the alkyl (meth)acrylate (a 2) can be arbitrarily combined.

Examples of the carboxy group-containing monomer (a 3) include (meth)acrylic acid, 2-acryloyloxyethyl hexahydrophthalic acid, 2-(meth)acryloyloxyethyl maleic acid, 2-(meth)acryloyloxypropyl maleic acid, 2-(meth)acryloyloxyethyl succinic acid, 2-(meth)acryloyloxypropyl succinic acid, crotonic acid, fumaric acid, maleic acid, and itaconic acid. These may be used alone or in combination of two or more kinds thereof.

Examples of the hydroxyl group-containing monomer (a 4) include hydroxyalkyl (meth)acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl (meth)acrylate; oxyalkylene-modified (meth)acrylates such as diethylene glycol (meth)acrylate and polyethylene glycol (meth)acrylate; primary hydroxyl group-containing (meth)acrylates such as 2-acryloyloxyethyl-2-hydroxyethyl phthalate; secondary hydroxyl group-containing (meth)acrylates such as 2-hydroxypropyl (meth)acrylate, 2-hydroxybutyl (meth)acrylate, and 3-chloro-2-hydroxypropyl (meth)acrylate; tertiary hydroxyl group-containing (meth)acrylates such as 2,2-dimethyl 2-hydroxyethyl (meth)acrylate; and vinyl ethers such as 2-hydroxyethyl vinyl ether, diethylene glycol monovinyl ether, and 4-hydroxybutyl vinyl ether. These can be used alone or in combination of two or more kinds thereof.

The adhesive sheet can be improved in adhesive force and can suppress moisture-heat whitening by the hydroxyl group-containing monomer (a 4).

Among the hydroxyl group-containing monomers (a 4), a hydroxyl group-containing monomer having, in a hydroxyalkyl group, 1 to 10 carbon atoms, more preferably 1 to 6 carbon atoms, and particularly preferably 2 to 4 carbon atoms, is preferable. For example, 2-hydroxyethyl (meth)acrylate, 4-hydroxybutyl (meth)acrylate, 2-hydroxypropyl (meth)acrylate, 2-hydroxyethyl vinyl ether, diethylene glycol monovinyl ether, or 4-hydroxybutyl vinyl ether is preferable; and a primary hydroxyl group-containing (meth)acrylate, for example, 2-hydroxyethyl (meth)acrylate or 4-hydroxybutyl (meth)acrylate is particularly preferable.

From the viewpoint of imparting the adhesive force and the moisture-heat whitening resistance properties, a contained amount of the unit derived from the hydroxyl group-containing monomer (a 4) in the copolymer (A) is preferably 0.1% to 15% by mass, more preferably 0.5% to 13% by mass, still more preferably 1% to 10% by mass, and particularly preferably 2% to 7% by mass.

Examples of the nitrogen-containing monomer (a 5) include an amino group-containing monomer, an amide group-containing monomer, an isocyanate group-containing monomer, and (meth)acrylonitrile. The adhesive sheet can be improved in cohesive force and can suppress moisture-heat whitening by the nitrogen-containing monomer (a 5). These may be used alone or in combination of two or more kinds thereof. In addition, the nitrogen-containing monomer (a 5) has an action of promoting a hydrogen abstraction reaction described later.

Examples of the amino group-containing monomer include primary amino group-containing (meth)acrylates such as aminomethyl (meth)acrylate and aminoethyl (meth)acrylate; secondary amino group-containing (meth)acrylates such as t-butylaminoethyl (meth)acrylate and t-butylaminopropyl (meth)acrylate; tertiary amino group-containing (meth)acrylates such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropyl acrylamide; N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, (meth)acryloylmorpholine, N-vinylacetamides, and N-vinylcaprolactam.

Examples of the amide group-containing monomer include (meth)acrylamide; N-alkyl (meth)acrylamides such as N-methyl (meth)acrylamide, N-ethyl (meth)acrylamide, N-propyl (meth)acrylamide, N-n-butyl (meth)acrylamide, diacetone (meth)acrylamide, and N,N′-methylene bis(meth)acrylamide; N,N-dialkyl (meth)acrylamides such as N,N-dimethyl (meth)acrylamide, N,N-diethyl (meth)acrylamide, N,N-dipropyl (meth)acrylamide, N,N-ethyl methyl acrylamide, and N,N-diallyl (meth)acrylamide; hydroxyalkyl (meth)acrylamides such as N-hydroxymethyl (meth)acrylamide and N-hydroxyethyl (meth)acrylamide; alkoxyalkyl (meth)acrylamides such as N-methoxymethyl (meth)acrylamide and N-(n-butoxymethyl) (meth)acrylamide; and maleimide or a derivative thereof.

Examples of the isocyanate group-containing monomer include 2-(meth)acryloyloxyethyl isocyanate and an alkylene oxide adduct thereof. The isocyanate group may be protected with a blocking agent such as methyl ethyl ketone oxime, 3,5-dimethylpyrazole, 1,2,4-triazole, and diethyl malonate.

Among the above, from the viewpoint of having a sensitizing action of a hydrogen abstraction reaction described later and thus being capable of efficiently forming crosslinking, a monomer having a tertiary nitrogen atom is preferable; and for example, a tertiary amino group-containing (meth)acrylate, N,N-dialkyl (meth)acrylamide, N-vinylpyrrolidone, or acryloylmorpholine is particularly preferable.

From the viewpoint of imparting the cohesive force and the moisture-heat whitening resistance properties, a contained amount of the unit derived from the nitrogen-containing monomer (a 5) in the copolymer (A) is preferably 0.1% to 15% by mass, more preferably 0.5% to 13% by mass, still more preferably 1% to 10% by mass, and particularly preferably 2% to 7% by mass.

Examples of the epoxy group-containing monomer (a 6) include glycidyl (meth)acrylate, methylglycidyl (meth)acrylate, 3,4-epoxycyclohexylmethyl (meth)acrylate, and 4-hydroxybutyl (meth)acrylate glycidyl ether. These may be used alone or in combination of two or more kinds thereof.

Examples of the vinyl monomer (a 7) include a compound having a vinyl group in the molecule. Examples of such a compound include vinyl ester monomers such as vinyl acetate, vinyl propionate, vinyl laurate, and vinyl stearate; and aromatic vinyl monomers such as styrene, chlorostyrene, chloromethylstyrene, α-methylstyrene, and other substituted styrenes. These may be used alone or in combination of two or more kinds thereof.

Examples of the alkyl (meth)acrylate monomer (a 8) with an alkyl group having 1 to 3 carbon atoms include methyl (meth)acrylate, ethyl (meth)acrylate, n-propyl (meth)acrylate, and i-propyl (meth)acrylate. These may be used alone or in combination of two or more kinds thereof.

From the viewpoint of imparting the cohesive force to the adhesive sheet, a contained amount of the unit derived from the alkyl (meth)acrylate monomer (a 8) in the copolymer (A) is preferably 0.1% to 15% by mass, more preferably 0.5% to 13% by mass, still more preferably 1% to 10% by mass, and particularly preferably 2% to 7% by mass.

Examples of the alicyclic monomer (a 9) include cyclohexyl (meth)acrylate, 3,3,5-trimethylcyclohexyl (meth)acrylate, isobornyl (meth)acrylate, dicyclopentanyl (meth)acrylate, dicyclopentenyloxyethyl (meth)acrylate, t-butylcyclohexyl (meth)acrylate, and adamantyl (meth)acrylate. These may be used alone or in combination of two or more kinds thereof.

From the viewpoint of imparting the cohesive force to the adhesive sheet, a contained amount of the unit derived from the copolymerizable monomer (a 9) in the copolymer (A) is preferably 0.1% to 15% by mass, more preferably 0.5% to 13% by mass, still more preferably 1% to 10% by mass, and particularly preferably 2% to 7% by mass.

The macromonomer (a 10) is a monomer capable of easily increasing the number of carbon atoms in a side chain to, for example, 20 or more, when a (meth)acrylic (co)polymer is polymerized. By using the macromonomer (a 10), a (meth)acrylic (co)polymer can be made into a graft copolymer having a segment having the unit derived from the macromonomer (a 10). It is preferable to use a graft copolymer from the viewpoint that the cohesive force of the copolymer (A) is improved and the cohesive force of the adhesive sheet is easily increased.

The characteristics of the main chain and the side chain of the graft copolymer can be changed depending on the selection of the macromonomer (a 10) and the other monomers, and on the blending ratio thereof.

It is preferable that the macromonomer (a 10) has a skeleton component composed of an acrylic copolymer or a vinyl-based polymer. Examples of the skeleton component of the macromonomer include the alkyl (meth)acrylate (a 2) with an alkyl having 4 to 30 carbon atoms, the vinyl monomer (a 7), the alkyl (meth)acrylate monomer (a 8) with an alkyl group having 1 to 3 carbon atoms, and the alicyclic monomer (a 9).

Among the above, it is preferable to use an alkyl (meth)acrylate with an alkyl group having 1 to 8 carbon atoms, an alicyclic monomer, or an aromatic monomer such as styrene, from the viewpoint that an adhesive sheet having exceptional cohesive force can be obtained.

On the other hand, it is preferable to use an alkyl (meth)acrylate with an alkyl group having 9 to 30, preferably 10 to 20 carbon atoms, from the viewpoint that an adhesive sheet having exceptional flexibility while having an appropriate cohesive force can be obtained.

These can be used alone or in combination of two or more kinds thereof.

The macromonomer has a radically polymerizable functional group or a functional group such as a hydroxyl group, an isocyanate group, an epoxy group, a carboxy group, an amino group, an amide group, and a thiol group. The macromonomer preferably has a radically polymerizable functional group which can be copolymerized with other monomers. One or two or more kinds of the radically polymerizable functional groups may be contained, and among these, one kind of the radically polymerizable functional group is particularly preferable. Even when the macromonomer has a functional group, the macromonomer may contain one or two or more functional groups; and among these, it is particularly preferable that the macromonomer contains one functional group.

In addition, the macromonomer may contain either one of the radically polymerizable functional group or the functional group or may contain both.

A weight-average molecular weight (Mw) of the macromonomer (a 10) is preferably 1,000 or more and 40,000 or less, more preferably 1,500 or more and 20,000 or less, and still more preferably 2,000 or more and 15,000 or less.

The weight-average molecular weight of the macromonomer (a 10) is a value in terms of standard polystyrene, which is measured by gel permeation chromatography (GPC).

As the macromonomer, a commercially available product (for example, a macromonomer manufactured by TOAGOSEI CO., LTD.) can be appropriately used.

A contained amount of the unit derived from the macromonomer (a 10) in the copolymer (A) is preferably 1% by mass or more and 30% by mass or less, more preferably 3% by mass or more and 20% by mass or less, and still more preferably 5% by mass or more and 15% by mass or less with respect to all units of the copolymer (A). When the contained amount is equal to or more than the above-described lower limit value, the force of phase separation between the segment having the unit derived from the macromonomer (a 10) and a segment consisting of other units is increased, and thus shape retention of the adhesive sheet in a non-bonded state tends to be more desirable. When the contained amount is equal to or less than the above-described upper limit value, the phase-separated structure tends to be easily destroyed during bonding, and thus unevenness followability tends to be more desirable. The lower limit and upper limit of the above-described contained amount can be arbitrarily combined.

Examples of the other copolymerizable monomers (all) include a (meth)acrylate having an alkoxyalkylene glycol skeleton, such as methoxydiethylene glycol (meth)acrylate, methoxypolyethylene glycol (meth)acrylate, butoxypolyethylene glycol (meth)acrylate, methoxypolypropylene glycol (meth)acrylate, butoxypolypropylene glycol (meth)acrylate, methoxypolytetramethylene glycol (meth)acrylate, butoxypolytetramethylene glycol (meth)acrylate, methoxypolyoxyethylene polyoxypropylene glycol (meth)acrylate, and butoxypolyoxyethylene polyoxypropylene glycol (meth)acrylate; and a heterocyclic ring-containing (meth)acrylate such as tetrahydrofurfuryl (meth)acrylate. These can be used alone or in combination of two or more kinds thereof.

From the viewpoint of obtaining an adhesive sheet having a high refractive index and exceptional flexibility, a proportion (a 10/a 1) of the unit derived from the macromonomer (a 10) to the unit derived from the aromatic (meth)acrylate (a 1) in the (meth)acrylic copolymer (A) is preferably 0.1 to 10 (weight ratio). Such a proportion (a 10/a 1) is more preferably 0.11 to 5, still more preferably 0.12 to 3, and particularly preferably 0.15 to 2.

A weight-average molecular weight (Mw) of the copolymer (A) is preferably 50,000 or more and 2,000,000 or less, more preferably 100,000 or more and 1,500,000 or less, and still more preferably 300,000 or more and 1,000,000. When the weight-average molecular weight of the copolymer (A) is equal to or more than the above-described lower limit value, the durability of the adhesive sheet after bonding tends to be improved. When the weight-average molecular weight of the copolymer (A) is equal to or less than the above-described upper limit value, moldability during adhesive sheet production tends to be improved. The lower limit and upper limit of the above-described weight-average molecular weight can be arbitrarily combined.

The weight-average molecular weight of the copolymer (A) is a value in terms of standard polystyrene, which is measured by gel permeation chromatography (GPC).

A melt viscosity of the copolymer (A) at 130° C. is preferably 20 Pa·s or more and 800 Pa·s or less, more preferably 50 Pa·s or more and 600 Pa·s or less, and still more preferably 100 Pa·s or more and 500 Pa·s or less. When the melt viscosity of the copolymer (A) at 130° C. is within the above-described range, it is possible to perform coating by a hot melt method in which the adhesive composition containing the copolymer (A) is heated and applied as it is. The lower limit and upper limit of the melt viscosity can be arbitrarily combined.

The melt viscosity can be measured, for example, using a viscoelasticity measuring device Rheosol-G5000 manufactured by UBM.

A method for producing the copolymer (A) is not particularly limited, and a known polymerization method can be used.

As the polymerization method, a known polymerization method such as a solution polymerization method, a suspension polymerization method, and an emulsion polymerization method can be used. In order to be used as an adhesive sheet, a solution polymerization method is preferable.

A contained amount of the copolymer (A) in the adhesive composition forming the adhesive sheet according to the embodiment is preferably 50% by mass or more and 99.5% by mass or less, more preferably 75% by mass or more and 99% by mass or less, and still more preferably 90% by mass or more and 98% by mass or less with respect to the total amount of the adhesive composition. The lower limit and upper limit of the contained amount of the copolymer (A) can be arbitrarily combined.

### (Photoinitiator (B))

It is preferable that the adhesive composition forming the adhesive sheet further contains a photoinitiator (B) in addition to the copolymer (A). When the adhesive composition contains the photoinitiator (B), the adhesive composition can have curability by active energy rays.

The photoinitiator (B) is a compound which generates active radical species when irradiated with light such as ultraviolet rays and visible light, more specifically, light having a wavelength of 200 nm to 780 nm.

The photoinitiator (B) can be appropriately selected from known photoinitiators. Examples thereof include a cleavage-type photoinitiator and a hydrogen abstraction-type photoinitiator.

Examples of the cleavage-type photoinitiator include 2,2-dimethoxy-1,2-diphenylethan-1-one, 1-hydroxycyclohexylphenylketone, 2-hydroxy-2-methyl-1-phenyl-propan-1-one, 1-(4-(2-hydroxyethoxy)phenyl)-2-hydroxy-2-methyl-1-propan-1-one, 2-hydrodooxy-1-[4-{4-(2-hydroxy-2-methyl-propionyl)benzyl}phenyl]-2-methyl-propan-1-one, oligo(2-hydroxy-2-methyl-1-(4-(1-methylvinyl)phenyl)propanone), 2-benzyl-2-dimethylamino-1-(4-morpholinophenyl)butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-dimethoxybenzoyl)2,4,4-trimethylpentylphosphine oxide, and a derivative thereof.

Examples of the hydrogen abstraction-type photoinitiator include intermolecular hydrogen abstraction-type photoinitiators such as benzophenone, 4-methylbenzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, 4-[(4-methylphenyl)thio]benzophenone, 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloxyethoxybenzophenone, 4-methacryloyloxy-4′-methoxybenzophenone, 4-methacryloxyethoxy-4′-methoxybenzophenone, 4-methacryloyloxy-4′-bromobenzophenone, and 4-methacryloxyethoxy-4′-bromobenzophenone; and intramolecular hydrogen abstraction-type photoinitiators such as methyl benzoylformate, oxyphenyl acetate-2-(2-oxo-2-phenylacetoxy-ethoxy)ethyl ester, and oxyphenyl acetate-2-(2-hydroxy-ethoxy)ethyl ester.

As the cleavage-type photoinitiator and the hydrogen abstraction-type photoinitiator, either one may be used, or both may be used in a mixed form. Furthermore, each of the cleavage-type photoinitiator and the hydrogen abstraction-type photoinitiator may be used alone or in combination of two or more kinds thereof.

The photoinitiator (B) preferably includes the hydrogen abstraction-type photoinitiator. When the photoinitiator (B) includes the hydrogen abstraction-type photoinitiator, a hydrogen abstraction reaction also occurs from the copolymer (A), and not only the photocurable compound (C) but also the copolymer (A) is incorporated into the crosslinked structure, and thus a crosslinked structure having a large number of crosslinking points can be formed. In addition, among the hydrogen abstraction-type photoinitiators, the intramolecular hydrogen abstraction-type photoinitiator is preferable because it can be a radical generation site not only of the hydrogen donor in the system but also of itself.

From the viewpoint of durability when forming a laminate from the adhesive sheet, a contained amount of the photoinitiator (B) in the adhesive composition forming the adhesive sheet is preferably 0.1 parts by mass or more, more preferably 0.3 parts by mass or more, still more preferably 0.5 parts by mass or more, and particularly preferably 1 part by mass or more with respect to 100 parts by mass of the copolymer (A). On the other hand, from the viewpoint of ensuring shape retention or pressure-sensitive adhesiveness of the adhesive sheet, the contained amount of the photoinitiator (B) is preferably 10 parts by mass or less, more preferably 5 parts by mass or less, still more preferably 3 parts by mass or less, and particularly preferably 2 parts by mass or less with respect to 100 parts by mass of the copolymer (A). The lower limit and upper limit of the contained amount of the photoinitiator (B) can be arbitrarily combined.

### (Photocurable Compound (C))

It is preferable that the adhesive composition forming the adhesive sheet further contains a photocurable compound (C), in addition to the copolymer (A) or in addition to the copolymer (A) and the photoinitiator (B).

When the adhesive composition further contains the photocurable compound (C), a curing efficiency by active energy rays can be improved, and thus the cohesive force after the active energy ray curing can be improved.

However, when the copolymer (A) can form a sufficient crosslinked structure in the present copolymer and/or between the present copolymers by a hydrogen abstraction reaction due to the action of the photoinitiator (B) or the like, the adhesive composition does not necessarily have to contain the photocurable compound (C).

The photocurable compound (C) is a compound having one or more radically polymerizable groups. As the radically polymerizable group, a (meth)acryloyl group is preferable.

Examples of the photocurable compound (C) include a monofunctional (meth)acrylic monomer, a polyfunctional (meth)acrylic monomer, and a (meth)acrylic oligomer.

The monofunctional (meth)acrylic monomer has one (meth)acryloyl group.

Examples of the monofunctional (meth)acrylic monomer include the monomers exemplified as the monomer forming the copolymer (A).

Examples of the polyfunctional (meth)acrylic monomer include a polyfunctional (meth)acrylic monomer having two (meth)acryloyl groups and a polyfunctional (meth)acrylic monomer having three or more (meth)acryloyl groups.

Examples of the polyfunctional (meth)acrylic monomer having two (meth)acryloyl groups include 1,4-butanediol di(meth)acrylate, glycerin di(meth)acrylate, neopentyl glycol di(meth)acrylate, glycerin glycidyl ether di(meth)acrylate, 1,6-hexanediol di(meth)acrylate, 1,9-nonanediol di(meth)acrylate, tricyclodecane dimethacrylate, tricyclodecane dimethanol di(meth)acrylate, bisphenol A polyethoxydi(meth)acrylate, bisphenol A polypropoxydi(meth)acrylate, bisphenol F polyethoxydi(meth)acrylate, ethylene glycol di(meth)acrylate, neopentyl glycol di(meth)acrylate, polyethylene glycol di(meth)acrylate, polypropylene glycol di(meth)acrylate, polytetramethylene glycol di(meth)acrylate, hydroxyvavallate neopentyl glycol di(meth)acrylate, and di(meth)acrylate with F-caprolactone adduct of hydroxyvavallate neopentyl glycol.

Examples of the polyfunctional (meth)acrylic monomer having three or more (meth)acryloyl groups include trimethylolpropane trioxethyl (meth)acrylate, F-caprolactone-modified tris(2-hydroxyethyl) isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, (tris(acryloxyethyl) isocyanurate, dipentaerythritol hexa(meth)acrylate, dipentaerythritol penta(meth)acrylate, tripentaerythritol hexa(meth)acrylate, tripentaerythritol penta(meth)acrylate, trimethylolpropane tri(meth)acrylate, trimethylolpropane polyethoxy tri(meth)acrylate, and ditrimethylolpropane tetra(meth)acrylate.

Among the above, from the viewpoint of imparting appropriate toughness to the cured product, a polyfunctional (meth)acrylic monomer having an alkylene glycol skeleton, such as polyethylene glycol di(meth)acrylate, polypropylene glycol di(meth)acrylate, and polytetramethylene glycol di(meth)acrylate, is more preferable.

From the viewpoint of imparting appropriate flexibility to the cured product, a molecular weight of the polyfunctional (meth)acrylic monomer is preferably 200 or more, more preferably 300 or more, still more preferably 400 or more, and particularly preferably 500 or more. The upper limit of the molecular weight of the polyfunctional (meth)acrylic monomer is usually 3,000 or less, preferably 2,000 or less.

As the (meth)acrylic oligomer, a monofunctional (meth)acrylic oligomer or a polyfunctional (meth)acrylic oligomer can be used. Examples thereof include polyester (meth)acrylate, epoxy (meth)acrylate, urethane (meth)acrylate, and polyether (meth)acrylate.

Among the above, from the viewpoint of imparting appropriate toughness to the cured product, polyfunctional urethane (meth)acrylate is preferable.

When the adhesive sheet according to the embodiment is cured, from the viewpoint that a cured product having high toughness is obtained, in other words, from the viewpoint that a cured product with appropriate flexibility is obtained, a molecular weight of the (meth)acrylic oligomer is preferably 3,000 or more, more preferably 5,000 or more, still more preferably 8,000 or more, and particularly preferably 10,000 or more. The upper limit of the molecular weight of the (meth)acrylic oligomer is usually 100,000 or less, preferably 50,000 or less.

From the viewpoint of easily imparting exceptional durability when forming a laminate from the adhesive sheet, a contained amount of the photocurable compound (C) in the adhesive composition forming the adhesive sheet is preferably 0.1 parts by mass or more, more preferably 0.5 parts by mass or more, still more preferably 1.0 parts by mass or more, and particularly preferably 1.2 parts by mass or more with respect to 100 parts by mass of the copolymer (A). On the other hand, from the viewpoint of ensuring shape retention or pressure-sensitive adhesiveness of the adhesive sheet, the contained amount of the photocurable compound (C) is preferably 10 parts by mass or less, more preferably 5 parts by mass or less, still more preferably 3 parts by mass or less, and particularly preferably 2 parts by mass or less with respect to 100 parts by mass of the copolymer (A). The lower limit and upper limit of the contained amount of the photocurable compound (C) can be arbitrarily combined.

### (Other Components)

Various additives such as a silane coupling agent, a viscosity imparting resin, a plasticizer, an antioxidant, a light stabilizer, a metal inactivator, an anti-aging agent, a moisture absorbent, a polymerization inhibitor, an ultraviolet absorber, an anticorrosive agent, inorganic particles, a sensitizer, and a pigment may be added to the adhesive composition forming the adhesive sheet, as necessary. It is preferable that the amount of these additives is typically set to not adversely affect the curing of the adhesive sheet or to not adversely affect the physical characteristics of the adhesive sheet.

### Method for Manufacturing Adhesive Sheet

A method for manufacturing the adhesive sheet according to the embodiment is not particularly limited. For example, the adhesive sheet according to the embodiment can be obtained by mixing predetermined amounts of the copolymer (A), preferably the photoinitiator (B), more preferably the photocurable compound (C), and an additive and the like to prepare an adhesive composition, molding the adhesive composition into a sheet shape, curing the adhesive composition by crosslinking, that is, a polymerization reaction, and appropriately processing the adhesive composition as necessary. Alternatively, the adhesive sheet according to the embodiment may be formed by preparing the adhesive composition as described above, coating an image display device constituent member with the adhesive composition, and curing the adhesive composition.

As a method of mixing each component, a method using a single-screw extruder, a twin-screw extruder, a planetary mixer, a twin-screw mixer, or a pressure kneader is an exemplary example.

As a method of molding the adhesive composition into a sheet shape, for example, a wet lamination method, a dry lamination method, a cast extrusion method using a T-die, an extrusion lamination method, a calendering or inflation method, an injection molding method, and a liquid injection curing method are exemplary examples.

The adhesive sheet according to the embodiment may be formed by dissolving the adhesive composition in an appropriate solvent and coating using various coating methods.

The adhesive composition can be cured by irradiating the composition with active energy rays. For example, the adhesive sheet according to the embodiment can be manufactured by irradiating, with active energy rays, a molded body of the adhesive composition, for example, a molded body obtained by molding the adhesive composition into a sheet body. In addition to the irradiation with active energy rays, the adhesive composition can be further cured by heating.

The irradiation energy, the irradiation time, the irradiation method, and the like with active energy rays are not particularly limited, and the monomer component may be polymerized by activating the photoinitiator.

Examples of the active energy ray to be radiated include ionizing radiation such as α-rays, β-rays, γ-rays, neutron beams, and electron beams, ultraviolet rays, and visible light. Among the above, from the viewpoint of suppressing damage to the image display device constituent member and controlling the reaction, ultraviolet rays are preferable.

As a light source for radiating the active energy ray, for example, a high-pressure mercury lamp, a metal halide lamp, a xenon lamp, a halogen lamp, an LED lamp, and a fluorescent lamp are exemplary examples.

From the viewpoint of sufficient curing, the irradiation amount of the active energy ray is preferably 1,000 mJ/cm² or more, more preferably 2,000 mJ/cm² or more, still more preferably 3,000 mJ/cm² or more, and particularly preferably 3,500 mJ/cm² or more. From the viewpoint of high curing efficiency, the irradiation amount is preferably 10,000 mJ/cm² or less, more preferably 7,000 mJ/cm² or less, and still more preferably 5,000 mJ/cm² or less. The lower limit and upper limit of the irradiation amount of the active energy ray can be arbitrarily combined.

Since the adhesive sheet according to the embodiment described above satisfies the requirement (1) and the requirement (2), the adhesive sheet has a high refractive index, is flexible, and is exceptional in flexibility. Therefore, the adhesive sheet according to the embodiment is suitable as a flexible image display device constituent member. In addition, the adhesive sheet is also suitable for bonding a member having unevenness on a surface and a member having an organic light emitting diode.

[Adhesive Sheet Equipped with Mold Release Film]

Another embodiment of the present disclosure relates to an adhesive sheet equipped with a mold release film.

In the adhesive sheet according to the embodiment, it is preferable that a mold release film is laminated on at least one surface of the adhesive sheet before bonding, and it is more preferable that mold release films are laminated on both surfaces thereof.

When the mold release film is provided on both surfaces of the present adhesive sheet, it is preferable to adopt a laminate configuration in which a lightly peeling film having a relatively low peeling force and a heavily peeling film having a relatively high peeling force are laminated. When the adhesive sheet equipped with a mold release film, having mold release films on both surfaces, is used, first, one release film (lightly peeling film) is peeled off to expose one surface of the adhesive sheet, the adhesive sheet is bonded to an image display device constituent member (referred to as a first member), and the other mold release film (heavily peeling film) is peeled off to bond the other surface of the exposed adhesive sheet to an image display device constituent member (referred to as a second member).

Examples of the mold release film include a polyester film, a polyolefin film, a polycarbonate film, a polystyrene film, an acrylic film, a triacetyl cellulose film, and a fluororesin film. Among the above, a polyester film or a polyolefin film is preferable, and a polyester film is more preferable.

In addition, since the film is easily peeled off from the adhesive sheet after irradiation with active energy rays, the mold release film is preferably a film having a peeling force of 0.1 N/cm or less measured under conditions of a peeling angle of 180° and a peeling rate of 300 mm/min.

From the viewpoint of processability and handleability, a thickness of the mold release film is preferably 25 μm or more and 500 μm or less, more preferably 38 μm or more and 250 μm or less, and still more preferably 50 μm or more and 200 μm or less. The lower limit and upper limit of the thickness of the mold release film can be arbitrarily combined.

### [Laminate for Image Display Devices]

Another embodiment of the present disclosure relates to a laminate for image display devices.

In the laminate for image display devices according to the embodiment, two image display device constituent members are laminated through the adhesive sheet according to the embodiment of the present disclosure.

Since the adhesive sheet according to the embodiment of the present disclosure has exceptional unevenness followability, the adhesive sheet is deformed by following the step on the surface of the image display device constituent member, and two image display device constituent members can be bonded together while absorbing the step. In addition, since the adhesive sheet has a high refractive index and is flexible and exceptional in flexibility, a difference in refractive index between the adhesive sheet and the member is small, and thus light scattering and the like are unlikely to occur at an interface between the adhesive sheet and the member, and a laminate for image display devices, having exceptional visibility, can be obtained.

Examples of the image display device constituent member constituting the present laminate for image display devices include a flat panel image display device constituent member and a flexible image display device constituent member. Examples of such an image display device constituent member include a liquid crystal display, a flexible display such as an organic electroluminescence (EL) display, a cover lens (cover film), a polarizing plate, a polarizer, a phase difference film, a barrier film, a viewing angle compensation film, a brightness improvement film, a contrast improvement film, a diffusion film, a semi-transmissive reflective film, an electrode film, a transparent conductive film, a metal mesh film, a touch sensor film, a light emitting element, a PSA, a color filter, and a flexible printed circuit board. Any one or two of these members can be used in combination. Examples of the combination include a combination of a flexible display and other image display device constituent members and a combination of a cover lens and other image display device constituent members.

A material of the image display device constituent member is not particularly limited. Examples thereof include resin sheets having, as a main component, a resin such as a urethane resin, a cycloolefin resin, a triacetyl cellulose resin, a (meth)acrylate resin, an epoxy resin, and a polyimide resin; thin film glass; and metals. The “main component” herein means a component having the highest mass ratio among components constituting the image display device constituent member, and the mass ratio is preferably 50% by mass or more, more preferably 55% by mass or more, and still more preferably 60% by mass or more.

The flexible image display device constituent member means a member which is a bendable member and used for an image display device having a curved surface shape, or a member which is repeatedly bendable. In particular, it is preferable that the flexible image display device constituent member is a member which can be fixed to a curved shape having a curvature radius of 25 mm or more, and particularly preferably a member which can withstand a bending action with a curvature radius of less than 25 mm, more preferably a curvature radius of less than 3 mm.

As described above, the image display device constituent member may have a step on the surface. For example, various unevenness may be present on a contact surface of the image display device constituent member with the adhesive sheet due to wiring, printing, pattern development, surface treatment, embossing, or the like.

A height difference of the step of the image display device constituent member is preferably 2 μm or more, more preferably 3 μm or more, and still more preferably 4 μm or more, and is preferably 10 μm or less, more preferably 8 μm or less, still more preferably 7 μm or less, and particularly preferably 6 μm or less. The lower limit and upper limit of the height difference of the step can be arbitrarily combined.

The step of the image display device constituent member on the contact surface with the adhesive sheet may be, for example, unevenness provided with a height difference of 2 to 10 μm and an interval of 10 mm or less.

From the viewpoint that the handleability is favorable, a thickness of the laminate for image display devices according to the embodiment is preferably 0.02 mm or more, more preferably 0.03 mm or more, and still more preferably 0.05 mm or more. From the viewpoint that the laminate can be made thinner, the thickness of the laminate for image display devices according to the embodiment is preferably 1.0 mm or less, more preferably 0.7 mm or less, and still more preferably 0.5 mm or less. The lower limit and upper limit of the thickness of the laminate for image display devices can be arbitrarily combined.

A method for manufacturing the laminate for image display devices according to the embodiment is not particularly limited.

For example, the adhesive composition may be applied onto the image display device constituent member to form an adhesive sheet, or an adhesive sheet equipped with a mold release film may be formed in advance and then bonded to the image display device constituent member.

A method of bonding the adhesive sheet on the surface of the image display device constituent member having a step is not particularly limited, and for example, a known method such as roll bonding, press bonding using a parallel plate, and diaphragm bonding can be used. A bonding environment may be an air bonding method of carrying out bonding at normal pressure or a vacuum bonding method of carrying out bonding under reduced pressure.

When bonding the adhesive sheet, a heating treatment may be performed. A heating temperature during the heating treatment is preferably 40° C. or higher and 100° C. or lower, more preferably 50° C. or higher and 90° C. or lower, and still more preferably 55° C. or higher and 85° C. or lower.

When bonding the adhesive sheet, a pressing pressure may be applied to the laminate together with the heating treatment.

In addition, when bonding the adhesive sheet, a pressurization treatment using an autoclave may be performed together with the heating treatment.

### [Flexible Image Display Device]

Still another embodiment of the present disclosure relates to a flexible image display device.

The “flexible image display device” means an image display device that does not leave any bending marks even after repeated bending, folding, or rolling up operations, and when released from the bent, folded, or rolled up state, quickly recovers to the state before the operation and displays images without distortion.

The flexible image display device according to the embodiment includes the laminate for image display devices according to the embodiment of the present disclosure. In the flexible image display device according to the embodiment, for example, the laminate for image display devices is disposed on a side of an image display panel opposite to the viewer side, that is, on a light source side.

In the flexible image display device according to the embodiment, other members may be further laminated between the image display panel and the laminate for image display devices according to the embodiment of the present disclosure or on a side of the laminate for image display devices according to the embodiment of the present disclosure opposite to the image display panel. Examples of the other members include the same image display device constituent members as those mentioned in the description of the laminate for image display devices according to the embodiment.

In the flexible image display device according to the embodiment, even when the image display device constituent member on the contact surface with the adhesive sheet has a step with, for example, a height difference of 2 μm or more, the adhesive sheet follows and absorbs the step, suppressing the generation of bubbles, and also suppresses delamination or cracking even when bent, folded, or rolled up in a low-temperature environment.

The present disclosure is not limited to the embodiments described above. Within a range not departing from the gist of the present disclosure, it is possible to appropriately substitute the constituent elements in the above-described embodiments with known constituent elements, and the above-described modification examples may be appropriately combined.

### EXAMPLES

Hereinafter, the embodiments will be described in more detail with reference to Examples, but the scope of the present disclosure is not limited to the description of Examples. “part” in Examples means “part by mass”.

### [Measurement and Evaluation]

Measurement and evaluation in Examples were carried out by the methods shown below.

### (Molecular Weight of Macromonomer)

A 0.2% by mass tetrahydrofuran solution of a macromonomer was prepared, and a weight-average molecular weight (Mw) in terms of standard polystyrene was determined under the following conditions.
GPC device: “HLC-8320” manufactured by Tosoh Corporation
Column: the following columns manufactured by Tosoh Corporation were used by being connected in series; as a guard column, “TSK guard column Super HZ-L” (4.6 mmID×2.0 cmL) manufactured by Tosoh Corporation was used;
two columns of “TSKgel super HZM-M” (4.6 mmID×15 cmL)
one column of “TSKgel Super HZ2000” (4.6 mmID×15 cmL)
Injection volume: 10 μL
Eluent: tetrahydrofuran (stabilizer: BHT)
Flow rate: 0.35 mL/min
Column temperature: 40° C.

### (Molecular Weight of (Meth)Acrylic Copolymer)

A 0.27% by mass tetrahydrofuran solution of a (meth)acrylic copolymer was prepared, and a weight-average molecular weight (Mw) in terms of standard polystyrene was determined under the following conditions.
GPC device: “HLC-8320” manufactured by Tosoh Corporation
Column: two columns “TSKgel Super HZM-H” (6.0 mmID×15 cmL) manufactured by TOSOH Corporation were connected in series and used; as a guard column, “TSK guard column Super HZ-IT” (4.6 mmID×3.5 cmL) manufactured by Tosoh Corporation was used.
Injection volume: 10 μL
Eluent: tetrahydrofuran (stabilizer: BHT)
Flow rate: 0.5 mL/min
Column temperature: 40° C.

### (Non-Volatile Content and Volatile Content)

Approximately 1 g of a sample was placed on an aluminum dish, dried in an oven equipped with a blower at 105° C. for 2 hours, the mass before and after the drying was measured on an electronic balance, and the concentration of non-volatile content was obtained according to the following expression.

$$Concentration of non - volatile content ( \% ) = ( Mass of sample after drying ( g ) / Mass of sample before drying ( g ) ) \times 100$$

A concentration of volatile content was determined from the determined concentration of non-volatile content according to the following expression.

$$Concentration of volatile content ( \% ) = 100 - Concentration of non - volatile content ( \% )$$

### (Refractive Index)

The mold release film on one side was removed from the adhesive sheet equipped with a mold release film, which was produced in each of Examples, and a refractive index was measured using an Abbe refractometer (manufactured by ATAGO Co., Ltd., model DR-A1-Plus) under measurement conditions of a wavelength of 589 nm and 23° C.

### (Storage Shear Modulus G′ and Tg of Adhesive Sheet)

The mold release film on one side was removed from an adhesive sheet equipped with a mold release film, which was produced in each of Examples, and the adhesive sheet was repeatedly laminated with a hand roller to adjust the thickness to approximately 0.8 mm, and punched out into a circle with a diameter of 8 mm to produce a sample. The obtained sample was placed in a rheometer (“DHR-2” manufactured by TA Instruments.), a dynamic viscoelasticity measurement was performed under the conditions of a measurement jig of 8 mm-diameter parallel plate, a frequency of 1 Hz, a measurement temperature of −50° C. to 150° C., and a temperature rising rate of 5° C./min, and a value of storage shear modulus G′ at −20° C., 25° C., 60° C., and 80° C. was read. From the measurement results, a value of G′(−20° C.)/G′(60° C.) was calculated. In addition, a temperature at which the maximal point of the loss tangent (tan δ) appeared was read as a glass transition temperature (Tg) of the adhesive sheet.

### (Creep Test)

The mold release film on one side was removed from an adhesive sheet equipped with a mold release film, which was produced in each example, and the adhesive sheet was repeatedly laminated with a hand roller to adjust the thickness to approximately 0.8 mm and punched out into a circle with a diameter of 8 mm to produce a sample. The obtained sample was placed in a rheometer (“DHR-2” manufactured by TA Instruments.), a strain (%) of the obtained sample after 600 seconds was measured under conditions of a measurement jig of 8 mm-diameter parallel plate, a temperature of 60° C., and a pressure of 2 kPa, and the measured value is regarded as a creep strain (maximum value).

### (Restoring Properties)

An operation in which the mold release film on one side was removed from the adhesive sheet equipped with a mold release film, and the adhesive sheet was repeatedly laminated with a hand roller to adjust the thickness to approximately 0.8 mm, and punched out into a circle with a diameter of 8 mm (a cylinder with a diameter of 8 mm and a height of approximately 0.8 mm) to produce a sample. For the obtained sample, using a viscoelasticity measuring device (“DHR-2” manufactured by TA Instruments), the maximum strain value (γₘₐₓ) when a stress of 2 kPa was applied at 60° C. for 600 seconds and a residual strain value (γₘᵢₙ) after 600 seconds from the point in time that the stress was removed were read, and a restoration rate was calculated from the following expression.

$$Restoration rate ( \% ) = [ ( {γ}_{max} - {γ}_{min} ) / {γ}_{max} ] \times 100$$

### (Gel Fraction)

The mold release film was removed from the adhesive sheet equipped with a mold release film, which was produced in each of Examples, to produce a sample.

The sample weighed in advance was wrapped with an SUS wire mesh of 150 mesh, and immersed in ethyl acetate at 23° C. for 24 hours. Thereafter, the sample was dried at 70° C. for 4.5 hours, and a mass of the insoluble sample remaining in the wire mesh after the immersion in ethyl acetate was measured. A mass percentage of the insoluble sample remaining in the wire mesh with respect to the mass of the sample before the immersion in ethyl acetate was calculated as a gel fraction (%).

### (Adhesive Force)

The mold release film on one side was removed from the adhesive sheet equipped with a mold release film, which was produced in each of Examples, and a PET film (thickness: 50 μm) was bonded thereto as a backing film using a hand roller. The laminate was cut into strips with a width of 10 mm and a length of 150 mm, the remaining mold release film was peeled off, and a PET film (manufactured by Mitsubishi Chemical Corporation, DIAFOIL S-100, thickness: 50 μm), which had been bonded to soda-lime glass in advance, was bonded to the exposed adhesive surface using a hand roller. The obtained laminate was subjected to an autoclave treatment (60° C., gauge pressure of 0.2 MPa, and 20 minutes) for finish bonding, thereby producing a measurement sample of adhesive force.

For the obtained measurement sample of adhesive force, the adhesive sheet was peeled off together with the backing film from the PET film bonded to the soda-lime glass while being pulled at a peeling rate of 300 mm/min at an angle of 180° under the conditions of 23° C. and 50% RH, and a tensile strength (N/cm) was measured with a load cell to obtain an adhesive force.

### (Total Light Transmittance)

The mold release film on one side was removed from the adhesive sheet equipped with a mold release film, which was produced in each of Examples, and the exposed adhesive surface was roll-pressed to soda-lime glass (82 mm×53 mm×0.55 mm (thickness)). Next, the remaining mold release film was peeled off, and the exposed adhesive surface was roll-pressed to another soda-lime glass (82 mm×53 mm×0.5 mm (thickness)). Thereafter, the obtained laminate was subjected to an autoclave treatment (60° C., gauge pressure of 0.2 MPa, and 20 minutes) for finish bonding, thereby producing a sample for measuring optical characteristics.

For the sample for measuring optical characteristics, a total light transmittance was measured using a haze meter (manufactured by NIPPON DENSHOKU INDUSTRIES Co., Ltd., NDH5000) in accordance with ISO-13468-1.

### [Used Material]

SLMA: mixture of an alkyl methacrylate having an alkyl group having 12 carbon atoms and an alkyl methacrylate having an alkyl group having 13 carbon atoms, manufactured by Mitsubishi Chemical Corporation; trade name: Acrylic Ester SL

POB-A: m-phenoxybenzyl acrylate, manufactured by Kyoeisha Chemical Co., Ltd. (refractive index: 1.566)

OPPEA: o-phenylphenoxyethyl acrylate, manufactured by Miwon Specialty Chemical Co., Ltd., trade name: Miramer M1142 (refractive index: 1.577)

PO-A: phenoxyethyl acrylate, manufactured by Kyoeisha Chemical Co., Ltd. (refractive index: 1.519)

AA: acrylic acid, manufactured by Mitsubishi Chemical Corporation

4HBA: 4-hydroxybutyl acrylate, manufactured by Mitsubishi Chemical Corporation

nBA: n-butyl acrylate, manufactured by Mitsubishi Chemical Corporation

2EHA: 2-ethylhexyl acrylate, manufactured by Mitsubishi Chemical Corporation

nOA: n-octyl acrylate, manufactured by OSAKA ORGANIC CHEMICAL INDUSTRY LTD.

MMA: methyl methacrylate, manufactured by Mitsubishi Chemical Corporation

AMBN: 2,2′-azobis(2-methylbutyronitrile), manufactured by Otsuka Chemical Co., Ltd.

### [Production Example 1]

100 parts of SLMA, 0.00075 parts of bis[(difluoroboryl)diphenylglyoxymate]cobalt(II) as a chain transfer agent, and 58 parts of ethyl acetate were charged into a four-necked flask equipped with a stirrer, a thermometer, a cooling tube, and a nitrogen gas inlet, and oxygen was replaced by nitrogen bubbling. Next, 0.4 parts of AMBN as a polymerization initiator and 2 parts of ethyl acetate were added thereto. Next, the external temperature was raised to 90° C. in a water bath, and the reaction was carried out in a reflux state for 2 hours. Next, 0.2 parts of AMBN and 20 parts of ethyl acetate were added dropwise thereto over 1 hour, and the reflux state was further maintained for 2 hours. Thereafter, the reaction solution was cooled to 40° C. to obtain a solution containing a macromonomer (SLMA-MM). By adding ethyl acetate to the solution, the concentration of non-volatile content was adjusted to 50% by mass. The weight-average molecular weight of the macromonomer (SLMA-MM) was 9,420.

### [Production Example 2]

900 parts of deionized water, 60 parts of sodium 2-sulfoethyl methacrylate, 10 parts of potassium methacrylate, and 12 parts of MMA were charged into a polymerization apparatus equipped with a stirrer, a cooling pipe, and a thermometer, and stirred, and the temperature was raised to 50° C. while replacing the inside of the polymerization apparatus with nitrogen. 0.08 parts of 2,2′-azobis(2-methylpropionamidine) dihydrochloride as a polymerization initiator was added thereto, and the temperature was further raised to 60° C. After the temperature was raised, MMA was continuously added dropwise thereto at a rate of 0.24 parts/min for 75 minutes using a drop pump. The reaction solution was maintained at 60° C. for 6 hours, and cooled to room temperature to obtain a dispersant 1 having a solid content of 10% by mass, which was a transparent aqueous solution.

145 parts of deionized water, 0.1 parts of sodium sulfate, and 0.25 parts of the dispersant 1 (solid content: 10% by mass) were charged into a polymerization apparatus equipped with a stirrer, a cooling pipe, and a thermometer, and stirred to obtain a uniform aqueous solution. Next, 100 parts of MMA, 0.0035 parts of bis[(difluoroboryl)diphenylglyoxymate]cobalt(II) as a chain transfer agent, and 0.35 parts of PEROCTA O (manufactured by NOF CORPORATION) as a polymerization initiator were added thereto to obtain an aqueous suspension. Next, the reaction was carried out for 1 hour in a state in which the inside of the polymerization apparatus was replaced with nitrogen and the temperature was raised to 80° C., and in order to further increase the polymerization rate, the temperature was raised to 90° C. and maintained for 1 hour. Thereafter, the reaction solution was cooled to 40° C. to obtain an aqueous suspension containing the macromonomer. The aqueous suspension was filtered, and the filtrate was washed with deionized water, dehydrated, and dried at 40° C. for 16 hours to obtain a macromonomer (MMA-MM) containing MMA as a unit.

The weight-average molecular weight of the macromonomer (MMA-MM) was 5,800.

### Example 1

### (Production of (Meth)Acrylic Copolymer)

25 parts of ethyl acetate as a charged solvent, 2 parts of isopropyl alcohol (IPA), and 15 parts of the macromonomer (SLMA-MM) solution (concentration: 50% by mass) were charged into a four-necked flask equipped with a stirrer, a thermometer, a cooling tube, and a nitrogen gas inlet, and the external temperature was raised to 85° C. in a water bath under nitrogen gas ventilation. After the reflux state was stabilized, a mixture consisting of 20 parts of ethyl acetate, 10 parts of POB-A, 75 parts of nBA, and 0.13 parts of NYPER BK40 MT (manufactured by NOF CORPORATION) was added dropwise thereto over 4 hours. After finishing the dropwise addition and retaining for 1 hour, a mixture consisting of 0.3 parts of PEROCTA O (manufactured by NOF CORPORATION) and 15 parts of ethyl acetate were added thereto over 1 hour. After retaining for 2 hours, 0.5 parts of “IRGANOX 1010” (trade name, manufactured by BASF) as an antioxidant, and 23 parts of ethyl acetate were added thereto, and the mixture was cooled to room temperature to obtain a (meth)acrylic copolymer (SLMA-MM/POB-A/nBA (mass ratio)=15/10/75, weight-average molecular weight: 510,000).

### (Production of Adhesive Sheet)

100 parts (solid content) of the (meth)acrylic copolymer, 1.5 parts of a (meth)acrylic oligomer as a photocurable compound (manufactured by Mitsubishi Chemical Corporation, SHIKOH UV-3700B), 1.5 parts of a photoinitiator (manufactured by IGM Resins B.V., Esacure TZT), and 154.5 parts of ethyl acetate are blended with each other to prepare an adhesive composition containing a solvent. The adhesive composition was developed in a sheet shape on a mold release film (manufactured by Mitsubishi Chemical Corporation, a PET film subjected to a silicone release treatment) having a thickness of 100 μm such that a thickness after drying was 50 m.

Next, the sheet-like adhesive composition together with the mold release film was put into a dryer heated to 90° C. and held for 10 minutes to volatilize the solvent contained in the adhesive composition. Furthermore, a mold release film (manufactured by Mitsubishi Chemical Corporation, a PET film subjected to a silicone release treatment) having a thickness of 75 μm was laminated on the sheet-like adhesive composition from which the solvent had been dried, and using a high-pressure mercury lamp, the adhesive composition was cured by irradiation with active energy rays through the mold release film with an irradiation amount such that the integrated light amount at a wavelength of 365 nm was 4,000 mJ/cm², thereby obtaining an adhesive sheet equipped with a mold release film, in which the mold release film was laminated on both front and back sides of a 50-μm thick adhesive sheet.

### Examples 2 to 11 and Comparative Examples 1 and 2

An adhesive sheet equipped with a mold release film was produced in the same manner as in Example 1, except that the copolymerization formulation of the (meth)acrylic copolymer was changed as shown in Table 1.

Table 1 shows the results of measurement and evaluation of the adhesive sheet of each example.

TABLE 1

| | | | | | Example | Example | Example | Example | Example | Example | Example |
|---|---|---|---|---|---|---|---|---|---|---|---|
| | | | | | 1 | 2 | 3 | 4 | 5 | 6 | 7 |
| (Meth)acrylic | (a1) | POB-A | | Part | 10 | 20 | 20 | 20 | 20 | 20 | 30 |
| copolymer | | OPPEA | | Part | — | — | — | — | — | — | — |
| | | PO-A | | Part | — | — | — | — | — | — | — |
| | (a2) | nBA | | Part | 75 | 65 | 41 | 25 | 25 | 11 | 15 |
| | | 2EHA | | Part | — | — | 28 | 40 | — | 58 | 48 |
| | | nOA | | Part | — | — | — | — | 40 | — | — |
| | | SLMA | | Part | — | — | — | — | — | — | — |
| | (a3) | AA | | Part | — | — | — | — | — | — | — |
| | (a4) | 4HBA | | Part | — | — | 4 | — | — | 4 | — |
| | (a10) | SLMA-MM | | Part | 15 | 15 | 7 | 15 | 15 | 7 | 7 |
| | | MMA-MM | | Part | — | — | — | — | — | — | — |
| | Weight-average | | | 10K | 51 | 56 | 74 | 44 | 64 | 69 | 55 |
| | molecular weight | | | | | | | | | | |
| Adhesive | Refractive | D-line | | — | 1.480 | 1.492 | 1.493 | 1.492 | 1.492 | 1.493 | 1.503 |
| sheet | index | | | | | | | | | | |
| | G′ | −20° | C. | kPa | 389 | 701 | 421 | 392 | 257 | 334 | 636 |
| | | 25° | C. | kPa | 39 | 42 | 35 | 23 | 19 | 23 | 25 |
| | | 60° | C. | kPa | 18 | 19 | 16 | 7 | 7 | 9 | 8 |
| | | 80° | C. | kPa | 12 | 13 | 12 | 4 | 5 | 6 | 6 |

| | | | | | | | | |
|---|---|---|---|---|---|---|---|---|
| G′(−20° C.)/G′(60° C.) | — | 22 | 37 | 26 | 56 | 37 | 37 | 75 |
| Glass transition | ° C. | −34 | −28 | −31 | −32 | −35 | −33 | −29 |
| temperature | | | | | | | | |
| Creep strain | % | 159 | 129 | 58 | 275 | 111 | 100 | 120 |
| (maximum value) | | | | | | | | |
| Restoration rate | % | 73 | 72 | 90 | 96 | 94 | 95 | 94 |
| Gel fraction | % | 51 | 50 | 69 | 51 | 61 | 71 | 60 |
| Adhesive force | N/cm | 5.9 | 6.4 | 5.2 | 5.2 | 3.6 | 3.9 | 5.6 |
| Total light | % | 91 | 91 | 91 | 91 | 91 | 91 | 91 |
| transmittance | | | | | | | | |

| | | | | Example | Example | Example | Example | Comparative | Comparative |
|---|---|---|---|---|---|---|---|---|---|
| | | | | 8 | 9 | 10 | 11 | Example 1 | Example 2 |
| (Meth)acrylic | (a1) | POB-A | Part | 20 | — | — | 20 | — | 20 |
| copolymer | | OPPEA | Part | — | 20 | — | — | — | — |
| | | PO-A | Part | — | — | 20 | — | — | — |
| | (a2) | nBA | Part | 41 | 41 | 41 | 11 | 85 | 11 |
| | | 2EHA | Part | 28 | 28 | 28 | 58 | — | 58 |
| | | nOA | Part | — | — | — | — | — | — |
| | | SLMA | Part | 7 | — | — | — | — | — |
| | (a3) | AA | Part | — | — | — | — | — | 4 |
| | (a4) | 4HBA | Part | 4 | 4 | 4 | 4 | — | — |
| | (a10) | SLMA-MM | Part | — | 7 | 7 | — | 15 | 7 |
| | | MMA-MM | Part | — | — | — | 7 | — | — |
| | Weight-average | | 10K | 53 | 56 | 32 | 59 | 46 | 47 |
| | molecular weight | | | | | | | | |
| Adhesive | Refractive | D-line | — | 1.493 | 1.495 | 1.486 | 1.496 | 1.468 | 1.495 |
| sheet | index | | | | | | | | |

| | | | | | | | | | |
|---|---|---|---|---|---|---|---|---|---|
| G′ | −20° | C. | kPa | 406 | 981 | 486 | 780 | 240 | 1768 |
| | 25° | C. | kPa | 27 | 35 | 34 | 55 | 35 | 47 |
| | 60° | C. | kPa | 10 | 11 | 13 | 28 | 16 | 15 |
| | 80° | C. | kPa | 7 | 6 | 8 | 21 | 11 | 9 |

| | | | | | | | |
|---|---|---|---|---|---|---|---|
| G′(−20° C.)/G′(60° C.) | — | 41 | 89 | 39 | 28 | 15 | 122 |
| Glass transition | ° C. | −32 | −25 | −30 | −30 | −37 | −21 |
| temperature | | | | | | | |
| Creep strain | % | 101 | 347 | 129 | 19 | 269 | 92 |
| (maximum value) | | | | | | | |
| Restoration rate | % | 95 | 64 | 77 | 88 | 68 | 90 |
| Gel fraction | % | 65 | 43 | 63 | 67 | 39 | 60 |
| Adhesive force | N/cm | 5.5 | 9.7 | 6.1 | 4.9 | 5.4 | 8.0 |
| Total light | % | 91 | 91 | 91 | 91 | 91 | 91 |
| transmittance | | | | | | | |

As shown in Table 1, the adhesive sheets of Examples 1 to 11 had a high refractive index of 1.480 or more. In addition, it was found that G′(−20° C.) was 10 kPa or more and 1,000 kPa or less, and thus the flexibility in a low-temperature environment was exceptional. Furthermore, the adhesive force was also favorable. In particular, it was found that the adhesive sheets of Examples 3 to 8 had a high restoration rate of 90% or more and thus had exceptional restoring properties in a case of being folded.

On the other hand, the adhesive sheet of Comparative Example 1 had a low refractive index as compared with the adhesive sheets of Examples.

In the adhesive sheet of Comparative Example 2, the storage shear modulus (G′(−20° C.)) at −20° C. was more than 1,000 kPa, and thus the flexibility in a low-temperature environment was deteriorated.

According to the present disclosure, it is possible to provide an adhesive sheet which has a high refractive index, is flexible, and is exceptional in flexibility, an adhesive sheet equipped with a mold release film, using the adhesive sheet, a laminate for image display devices, and a flexible image display device.

What is claimed is:

1. An adhesive sheet comprising a cured product of an adhesive composition,
wherein the adhesive composition comprises a (meth)acrylic copolymer (A), and
the following requirements (1) and (2) are satisfied,
the requirement (1): a refractive index of the adhesive sheet is 1.480 or more and less than 1.550,
the requirement (2): a storage shear modulus G′(−20° C.) at −20° C., which is obtained by a dynamic viscoelasticity measurement in a shear mode at a frequency of 1 Hz, is 10 kPa or more and 1,000 kPa or less.

2. The adhesive sheet according to claim 1,
wherein the (meth)acrylic copolymer (A) includes a unit derived from an aromatic (meth)acrylate (a 1) having a refractive index of 1.500 or more.

3. The adhesive sheet according to claim 2,
wherein a glass transition temperature (Tg) of a homopolymer of the aromatic (meth)acrylate (a 1) is 60° C. or lower.

4. The adhesive sheet according to claim 2,
wherein a proportion of the unit derived from the aromatic (meth)acrylate (a 1) to all units of the (meth)acrylic copolymer (A) is 1% to 50% by mass.

5. The adhesive sheet according to claim 1,
wherein a glass transition temperature (Tg) defined by a maximal value of Tan δ, which is obtained by the dynamic viscoelasticity measurement in the shear mode at the frequency of 1 Hz, is −20° C. or lower.

6. The adhesive sheet according to claim 1,
wherein the adhesive composition further comprises a photoinitiator (B).

7. The adhesive sheet according to claim 1,
wherein the adhesive composition further comprises a photocurable compound (C).

8. The adhesive sheet according to claim 1,
wherein the adhesive composition further comprises a photoinitiator (B) and a photocurable compound (C).

9. The adhesive sheet according to claim 1,
wherein a ratio G′(−20° C.)/G′(60° C.) of the storage shear modulus G′(−20° C.) at −20° C. to a storage shear modulus G′(60° C.) at 60° C., which is obtained by the dynamic viscoelasticity measurement in the shear mode at the frequency of 1 Hz, is 150 or less.

10. The adhesive sheet according to claim 1,
wherein a restoration rate calculated by the following expression from a maximum strain value (γₘₐₓ) when a stress of 2 kPa is applied to the adhesive sheet at 60° C. for 600 seconds and a residual strain value (γₘᵢₙ) after 600 seconds from a point in time that the stress is removed is 60% or more,
$$the restoration rate ( \% ) = [ ( {γ}_{max} - {γ}_{min} ) / {γ}_{max} ] \times 100.$$

11. The adhesive sheet according to claim 1,
wherein a gel fraction is 30% or more.

12. The adhesive sheet according to claim 1,
wherein the (meth)acrylic copolymer (A) has a unit derived from an alkyl (meth)acrylate with an alkyl group having 9 to 30 carbon atoms.

13. The adhesive sheet according to claim 1,
wherein the (meth)acrylic copolymer (A) is a block copolymer or a graft copolymer.

14. The adhesive sheet according to claim 1,
wherein the (meth)acrylic copolymer (A) has a unit derived from a macromonomer (a 10).

15. The adhesive sheet according to claim 14,
wherein the macromonomer (a 10) has a unit derived from an alkyl (meth)acrylate with an alkyl group having 9 to 30 carbon atoms.

16. The adhesive sheet according to claim 14,
wherein the (meth)acrylic copolymer (A) further has a unit derived from an aromatic (meth)acrylate (a 1) having a refractive index of 1.500 or more, and
a proportion (a 10/a 1) of the unit derived from the macromonomer (a 10) to the unit derived from the aromatic (meth)acrylate (a 1) in the (meth)acrylic copolymer (A) is 0.1 to 10 in terms of weight ratio.

17. The adhesive sheet according to claim 1,
wherein the adhesive sheet is used for bonding a member having unevenness on a surface and a member having an organic light emitting diode.

18. An adhesive sheet equipped with a mold release film, comprising:
the adhesive sheet according to claim 1; and
a mold release film laminated on at least one surface of the adhesive sheet.

19. The adhesive sheet according to claim 1,
wherein the adhesive sheet is used for a flexible image display device constituent member.

20. A laminate for image display devices, comprising:
two image display device constituent members; and
the adhesive sheet according to claim 1,
wherein the two image display device constituent members are laminated through the adhesive sheet, and
at least one of the two image display device constituent members has a step with a height difference of 2 μm or more on a contact surface with the adhesive sheet.

21. A flexible image display device comprising:
the laminate for image display devices according to claim 20.
